(19) United States
(12) Patent Application Publication
(10) Pub. No.: US 2013/0342087 A1
(43) Pub. Date: Dec. 26, 2013

(54) DEVICE HOLDER ASSEMBLY AND DISPLAY STAND ASSEMBLY FOR TABLET COMPUTERS OR THE LIKE

(71) Applicant: BONZAI DESIGN GROUP INC., Elmira (CA)

(72) Inventor: Iles Z. Guran, Elmira (CA)

(73) Assignee: BONZAI DESIGN GROUP INC., Elmira (CA)

(21) Appl. No.: 13/974,392

(22) Filed: Aug. 23, 2013

Related U.S. Application Data
(63) Continuation-in-part of application No. 13/591,548, filed on Aug. 22, 2012.
(60) Provisional application No. 61/529,863, filed on Aug. 31, 2011.

(51) Int. Cl. H05K 5/00; F16M 11/00

(52) U.S. Cl. CPC H05K 5/0017; F16M 11/00
USPC 312/7.2

(57) ABSTRACT

The display stand assembly for a tablet computer or the like has a support structure and a device holder assembly secured to the support structure. The device holder assembly includes a housing which defines an insert cavity sized larger than the device. At least one insert is positionable within the insert cavity and defines a device cavity sized to receive the device. A face plate with an optional separate frame is securable to the housing over the insert(s) and device, to secure the device and show the display screen while denying physical access to parts of the device. In one alternative embodiment, at least one mounting plate is provided in the housing, and each insert is positionable in any one of a number of positions on the mounting plate(s), thus permitting standardization of the inserts regardless of the electronic device being used. The insert(s) may include a platform which is adjustable in height to accommodate different device thicknesses.

### REFERENCE TO RELATED APPLICATION(S)

This application is a continuation-in-part of application Ser. No. 13/591,548, filed Aug. 22, 2012, which is a formal application based on and claiming the benefit of provisional application Ser. No. 61/529,863, filed Aug. 31, 2011.

### BACKGROUND OF THE INVENTION

This invention relates to device holder assemblies and display stand assemblies, particularly for tablet computers, electronic touchpads, electronic books, or other electronic handheld or multimedia devices. For convenience, such devices will be generally referred to as “electronic display devices” herein. The expression “device holder assembly” will be used generally to denote the structure which actually holds or captures the electronic display device, whereas “display stand assembly” may include some additional structure in addition to the device holder assembly, such as a support structure to position the device holder assembly at a desired height and/or in a desired orientation.

Often, it is desirable to provide people with access to certain functions of an electronic display device such a tablet computer, without giving them access to all functions of the device. For example, at a trade show, it may be desirable to allow visitors to select certain information to be displayed, but undesirable to permit them to turn the device off, or switch to unauthorized functions. Physically blocking access to parts of the device is often the most desirable solution.

An Apple iPad, for example, has a touch-responsive display surrounded by a frame. The frame has a single control or “home” button. Blocking or restricting physical access to that home button may be desired. (The iPad also permits access to certain control functions via certain finger-swipe gestures, but those can be disabled.) The iPad, and other devices, may also have one or more camera lenses, which it may or may not be desirable to cover, depending on the application.

It is also necessary or at least highly desirable to provide physical security for the electronic display device, so that it cannot be easily stolen from the device holder or display stand assembly.

It is also desirable for a device holder assembly or display stand assembly to be relatively light in weight.

It is also desirable to be able to use a device holder assembly or display stand assembly with a variety of devices, including (without limitation), iPad® tablets, Android® tablets and Windows® tablets.

It is also desirable in many situations to be able to use a display stand assembly in more than a single configuration, and to be able to disassemble it easily for portability and shipment.

### BRIEF SUMMARY OF THE INVENTION

In view of the preceding, it is a goal of the invention to provide a device holder assembly which responds to some or all of the above objectives.

It is a further goal to provide display stand assemblies which include the device holder assembly.

The device holder assembly includes a housing defining an insert cavity sized larger than the device; at least one insert positionable within the insert cavity, the insert(s) having inner surfaces defining a device cavity configured to receive the device; and a face plate securable to the housing over the insert(s) and device, the face plate having an opening sufficiently large to expose a desired display area of the device. Thus devices of different sizes may be used in the device holder assembly by selection of insert(s) defining a device cavity appropriately sized and shaped for the selected device.

Preferably, the device holder assembly also includes a frame positioned between the face plate and the housing to overlie the device, having an opening sufficiently large to expose the display area of the device. This allows one size of face plate opening to be used for a wide variety of devices, by providing device-specific frames with appropriately-sized openings for the specific devices. This is especially advantageous since a variety of frames can be provided much less inexpensively than a variety of face plates, since they can be much less robust (a thin sheet of plastic for example), with no complex machining or molds required.

According to one embodiment of the invention, for devices of different sizes, kits can be provided which consist simply of the appropriate inserts, and an appropriate frame or frames, for use with a standardized housing. It may be desirable to provide more than one frame for a given device, to provide flexibility as to which features of the device are to be covered and which are to be revealed.

There can be one, two or more inserts to define the device cavity. Having four inserts is optimal in terms of maximum flexibility, lower material cost, and maximum internal space for any necessary or desireable cable routing, etc.

In a preferred embodiment of the invention, instead of having different-sized inserts for different devices, standardized inserts may be used, installable in any one of a number of positions provided by one or more mounting plates. Preferably, there are four mounting plates, i.e. one for each corner of the unit, and four inserts. The inserts may be mounted in a variety of locations on the mounting plates, by any desired means, for example by providing the inserts with projecting pins which engage selected holes in the mounting plates. The mounting plates may be secured to the housing by any desired means, or may be integral to the housing.

The inserts may also include a height adjustment feature, such as platforms which may be raised or lowered to allow for devices of different thicknesses.

The device holder assemblies may be mounted directly on a surface, or on a support structure, to position the displays in a desired location. In a display stand assembly which includes the support structure, the display stand assembly preferably is configurable in several ways (e.g. as a floor display, as a table-top display and as a wall display).

Further details of the invention will be described or will become apparent in the course of the following detailed description and in the accompanying drawings of specific examples of the invention.

### BRIEF DESCRIPTION OF THE DRAWINGS

Preferred and alternative embodiments of the invention will now be described, by way of example only, with reference to the attached drawings, in which:

FIG. 1 is a perspective view of an example of a floor display configuration of a display stand assembly according to the invention;

FIG. 2 is an exploded perspective view corresponding to FIG. 1, using two inserts;

FIG. 3 is an exploded perspective view of the device holder assembly of FIGS. 1 and 2;

FIG. 4 is an exploded perspective view showing an alternative insert configuration, namely one using a one-piece insert;

FIG. 5 is an exploded perspective view showing another alternative insert configuration, namely one using four inserts;

FIG. 6 is a perspective view of a connector for connecting the housing to the support structure of the stand;

FIG. 7 is a rear perspective view of an embodiment with a ball joint between the support structure and the device holder assembly;

FIG. 8 is a perspective view of an example of a table-top configuration;

FIG. 9 is an exploded perspective view of a double-ended connector between two tubing sections of the support structure;

FIG. 10 is a perspective view of an example of a wall mount configuration;

FIG. 11 is a plan view of the housing of an alternative embodiment of the device holder assembly, featuring mounting plates on which inserts may be positioned in a variety of locations;

FIG. 12 is a plan view corresponding to FIG. 11, but showing a device installed;

FIG. 13 is an exploded perspective view of the FIG. 11 embodiment;

FIG. 14 is a view showing one example of how the mounting plates may be installed in the housing;

FIG. 15 is a perspective view of one of the inserts for the FIG. 11 embodiment, with a height (device thickness) adjustment feature; and

FIG. 16 is another perspective view of the FIG. 15 insert, from underneath.

### DETAILED DESCRIPTION OF THE INVENTION

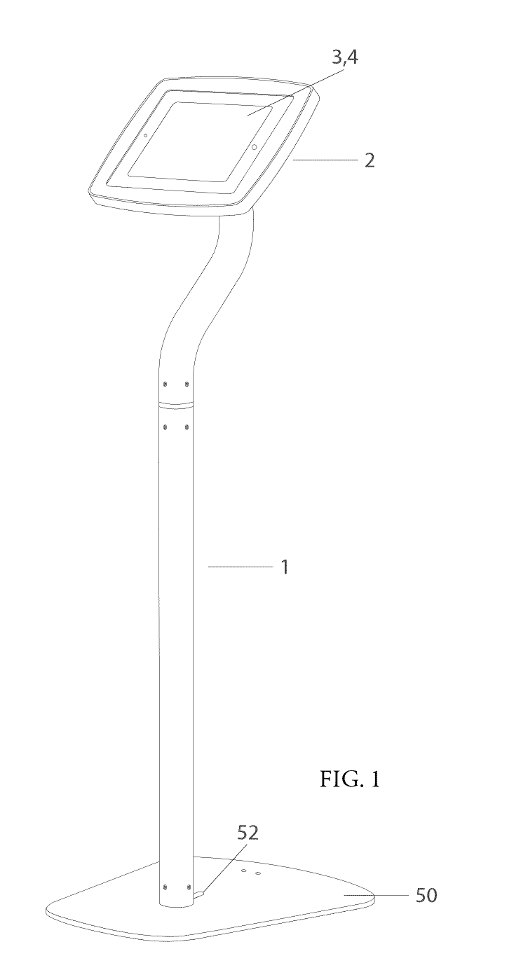

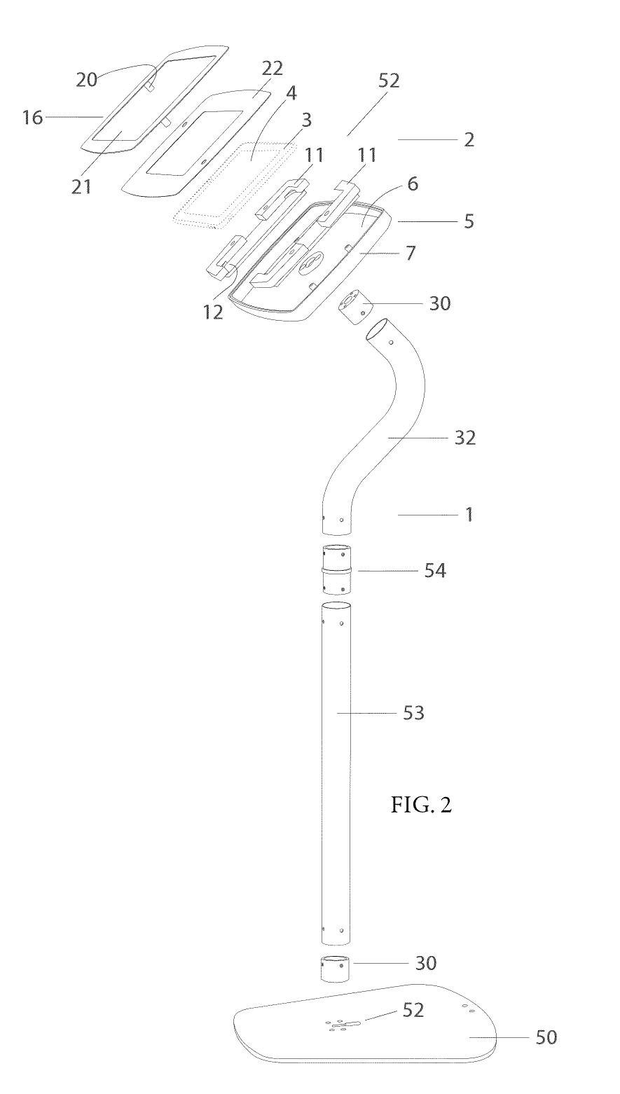

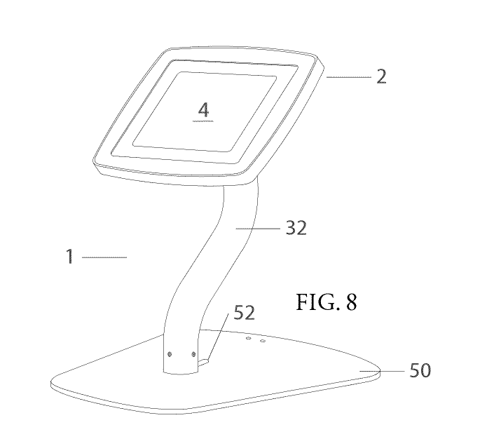

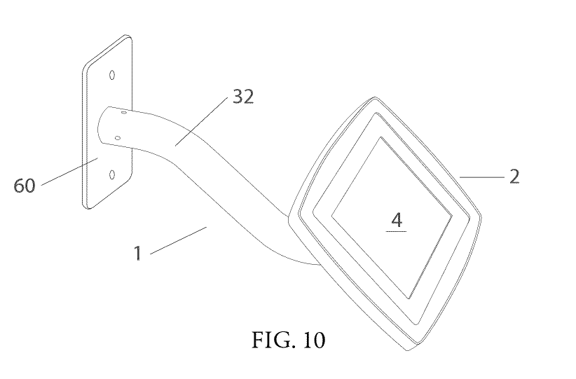

FIGS. 1 to 7 show a display stand assembly having a support structure 1 and a device holder assembly 2 which holds an electronic display device 3 with its display 4 exposed (and any device controls which are desired to be exposed). The support structure in this example is for a floor display, but the support structure can be varied depending on where the assembly is to be installed. Two other examples of the display stand assembly are described herein, namely a table top configuration (see FIG. 8) and a wall mount configuration (see FIG. 10). Obviously other configurations could be adopted, using the principles and main features of the invention.

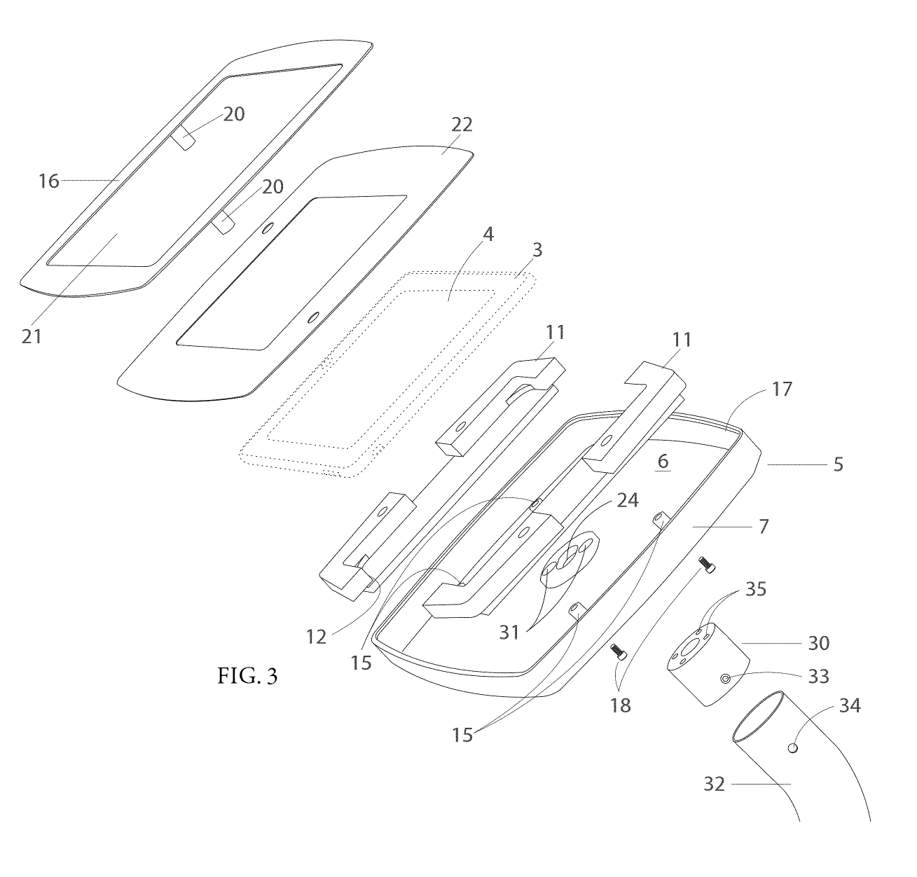

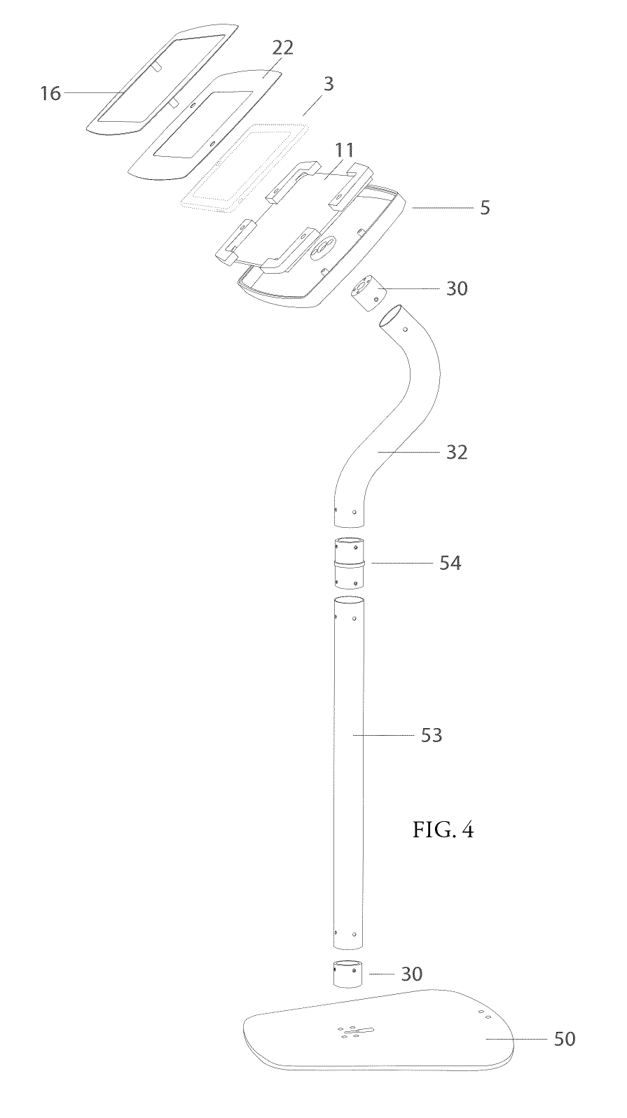

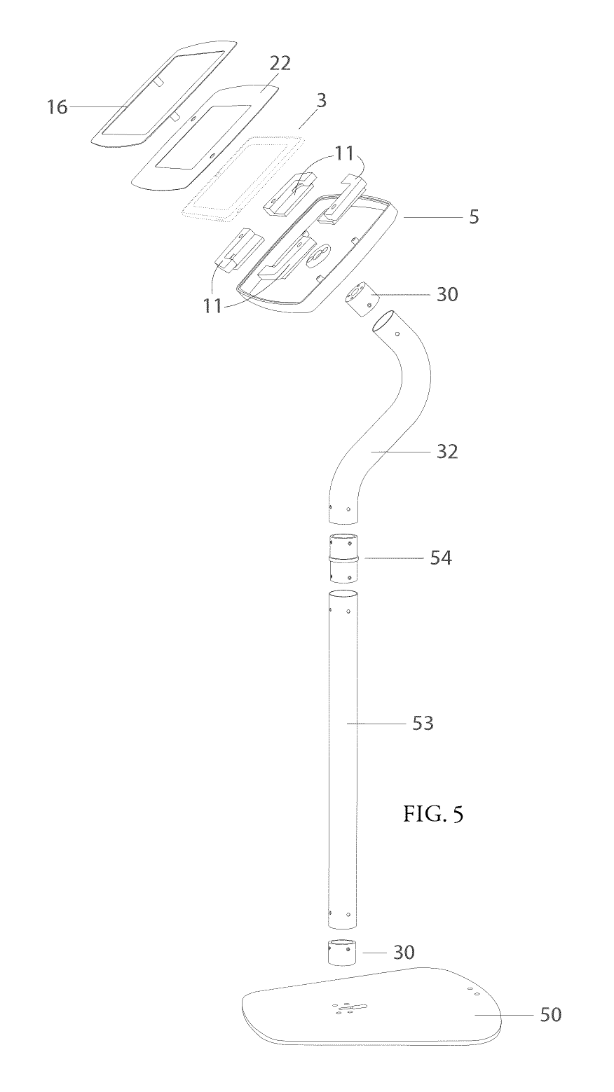

As seen best in FIG. 3, the device holder assembly 2 of this embodiment includes a housing 5 having a rear surface 6 and surrounding walls 7. The housing defines an insert cavity sized larger than the device, to receive at least one replaceable insert 11 positionable within the insert cavity. In this example, two such inserts 11 and 11′ are illustrated. However, it should be understood that a single insert could be used, as illustrated in FIG. 4, or there could be four inserts as illustrated in FIG. 5 and as described in the provisional application upon which this application is based. Regardless of the number of inserts, the insert(s) provide(s) inner surfaces 12 defining a device cavity, the device cavity being sized to receive the device 3, both in terms of the device's shape and dimensions and in terms of its depth. Devices of different sizes may be used in the display stand assembly by selection of insert(s) defining a device cavity appropriately sized for the selected device.

The insert(s) 11 is/are preferably held in place by pins 15 extending from the rear surface 6 of the housing, engaging corresponding holes in the insert(s), but obviously could be retained by other means.

It is advantageous to use two or four inserts instead of just one, in terms of weight and amount of material used, and therefore production costs, especially for larger device holder assemblies. Using more than one insert also provides more interior space, which may be required for cabling and any necessary or desired connections to the device.

A face plate 16 sits in a recess 17 of the housing, and is secured to the housing over the insert(s) 11, 11′ and the device 3, preferably by Torx™ security screws 18 or the like, passing from the back of the rear surface 6 through holes in the insert(s) 11 and frame 22 and screwing into studs 20. The studs may have a short male thread on one end which screws into the face plate from the back to sit flush with the front of the face plate, or preferably they are welded in place and ground flush for a smooth outer surface of the face plate. The other ends of the studs have a female threaded opening (not shown) to receive the screws 18. The use of Torx™ security screws or the like is preferred, so that the assembly cannot be dismantled casually by just anyone, a special tool being required to loosen the screws.

The surrounding walls 7 in this embodiment are part of the housing. However, if desired for some reason, the walls could be part of the face plate instead of the housing, or the face plate and the housing could together define the walls.

The housing and face plate preferably are machined from aluminum, but other sufficiently robust materials obviously could be used. Injection molded plastic is presently being considered, for example. In a current embodiment, the housing is ABS and the face plate is steel.

The face plate 16 has an opening 21 sufficiently large to expose the display area 4 of the device. Thus the face plate 16 itself can act as the desired frame or cover for the device, if the opening 21 is suitably sized for the device and provided with any necessary openings for any permitted access to device controls, volume buttons, camera lenses, etc. However, in a preferred example of the invention, a separate frame 22 is provided, for positioning between the face plate 16 and the device 3. This facilitates using the assembly for different devices, since a kit for any given device can be provided, consisting of the insert(s) 11 and a frame or frames 22 specific to the device, with the face plate 16 being sized for the largest device intended to be accommodated.

As stated previously above, it may be desirable to provide more than one frame for a given device, to provide flexibility as to which features of the device are to be covered and which are to be revealed. Using the Apple iPad as an example, in some applications it may be desirable to have everything covered except the display (possibly with pin-hole access to the home button via a small hole through the face plate and/or frame). In other applications, it may be desirable leave the home button and/or the front camera lens exposed, for example.

For some installations, it may also be necessary or desirable to provide small holes through the housing and/or face plate, to provide access to on/off switches or the like.

The insert(s) 11 must take into account the location of various plugs and peripheral attachments which the device may require, i.e. the inserts must be configured so as not to block any necessary connection points and so as to provide for routing of power cords or other necessary cables. To provide for cable access in a way that is both secure and aesthetic, the support structure 1 is preferably hollow. Metal tubing is therefore preferred. As can be seen in FIG. 3, cabling to or from the device can be routed through a hole 24 in the rear surface 6 of the inside of the housing 5, and thence down through the tubing 32 of the support assembly. The area around the hole is preferably thicker than the rest of the rear surface, for added strength. The connector 30 and any connectors 54 between tubing sections are therefore also not solid, but instead have central openings. A cutout 52 provides for passage of cables from the tubing. In a permanent installation, instead of using the cutout 52, cabling can be routed through a hole in the floor, table top or wall, so that nothing is exposed.

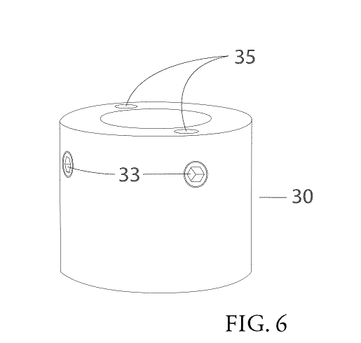

The support structure 1 will now be described in more detail. A connector 30 as shown in FIG. 6, made of machined plastic for example, is secured to the outside of the rear surface 6 of the housing by two screws (not shown) screwed through holes 31 in the plate 25 from inside the housing, into threaded holes 35 in the connector. A generally S-shaped tube 32 slides onto the connector and is secured to it by four set screws 33 through holes 34 in the S-shaped tube screwing into threaded holes in the connector. For convenience of assembly, the set screws are turned in flush to the connector before a connection and then once the tube is in position over the connector, the screws are turned counterclockwise through the holes 34 to fasten the tube in place and add rigidity to the connection. Obviously, other connection means could be used if desired. For anti-theft reasons, however, quick-release connections generally should not be used, unless theft is not a concern.

Since there are four set screws 33 and holes 34 offset from each other by ninety degrees, the device holder assembly 2 can be oriented in any one of four orientations, including of course either portrait or landscape viewing of the device. Similarly, there are four holes 35 in the connector, affording an alternative means of orienting the device holder assembly.

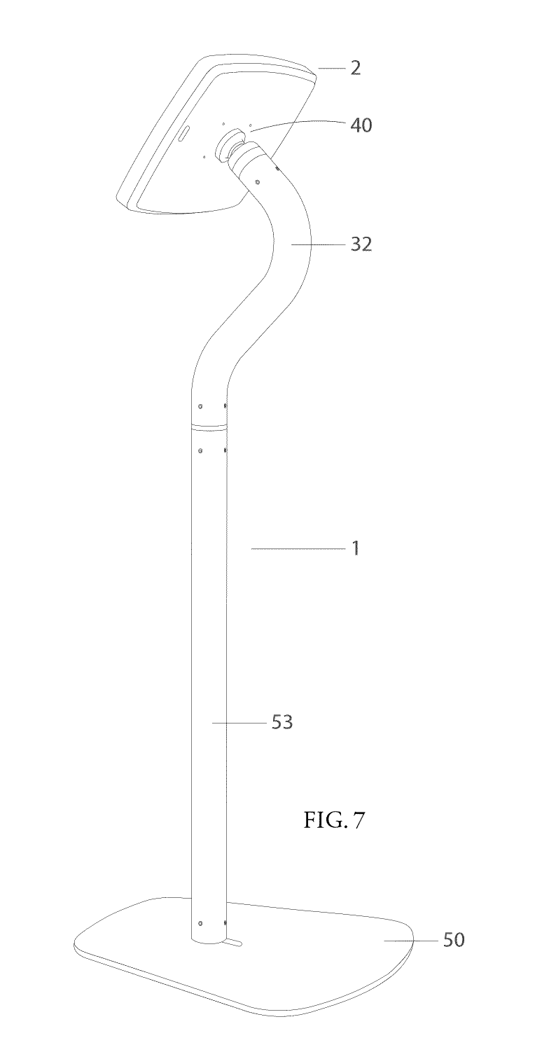

As an alternative, as shown in FIG. 7, the connector 30 (not visible in FIG. 7) could be secured to a ball joint assembly 40, and thence to the tube 32, so that the angle of the display could be varied, and/or so that the display could be rotated.

As can be appreciated from the drawings, the S-shape of the tube 32 positions the housing at an optimum viewing angle, and also puts the center of gravity of the device generally over the support assembly to reduce any tipping potential. (Of course it will generally be preferable to secure the device to the floor or table top in any event.)

For a table top version of the display stand assembly, as shown in FIG. 8 a base plate 50 is secured to the bottom of the S-shaped tube 32, in the same manner as the housing is connected, i.e. by using a connector identical to the connector 30. Four screws from under the base plate thread into the connector, and the bottom of the tube 32 slides over the connector and is secured thereto in the same manner as described above for the connector. For easier storage and portability, the base plate can comprise two separate pieces, or in one piece as illustrated. In either case, the cutout 52 provides for passage of cables through from beneath and into the connector and tubes.

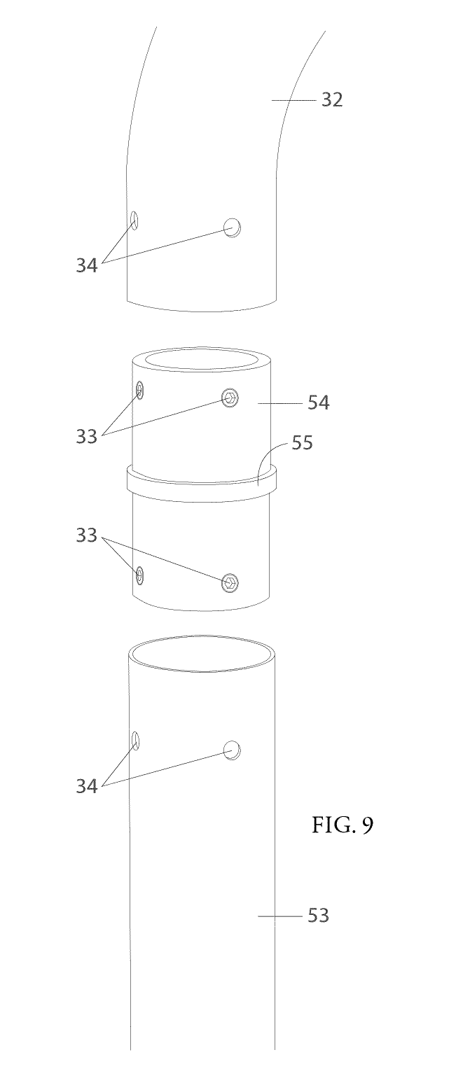

For a floor version of the display stand assembly, an extension tube 53 is inserted between the base plate 50 and the S-shaped tube 32 as shown in FIG. 9. A double-ended connector 54 is used to connect the extension tube to the S-shaped tube, in the same manner as with the connector 30 and the base connector 51. A central flange 55 facilitates assembly, by preventing the connector from falling into the tube. Alternatively, of course a one-piece tube could be used, i.e. extending from the base to the device holder assembly.

For a wall-mount version of the display stand assembly, the S-shaped tube is connected to a wall mount plate 60, as shown in FIG. 10, securable to a wall.

For any of these configurations, the installation may be either permanent or temporary. For temporary installations, such as at a trade show, it can be seen that the assembly is relatively quick and easy to disassemble, given the proper tools to unscrew the security screws.

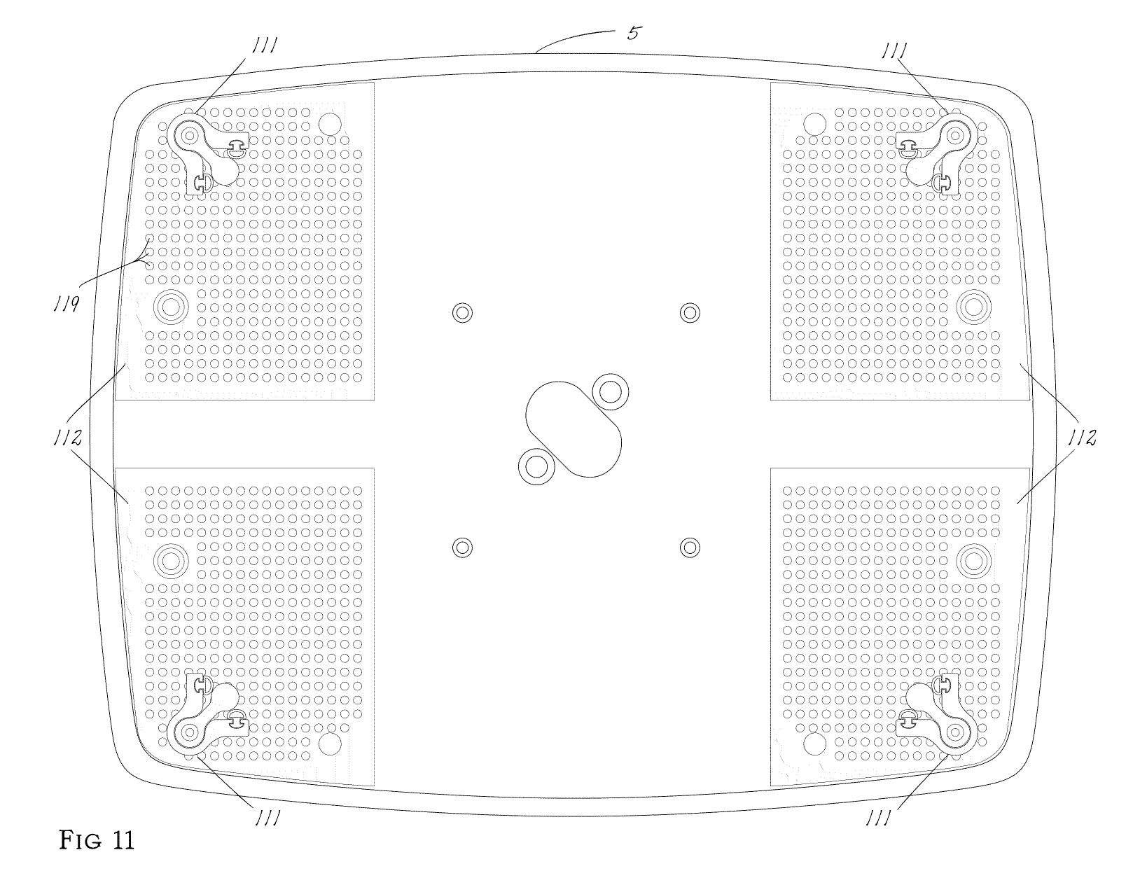

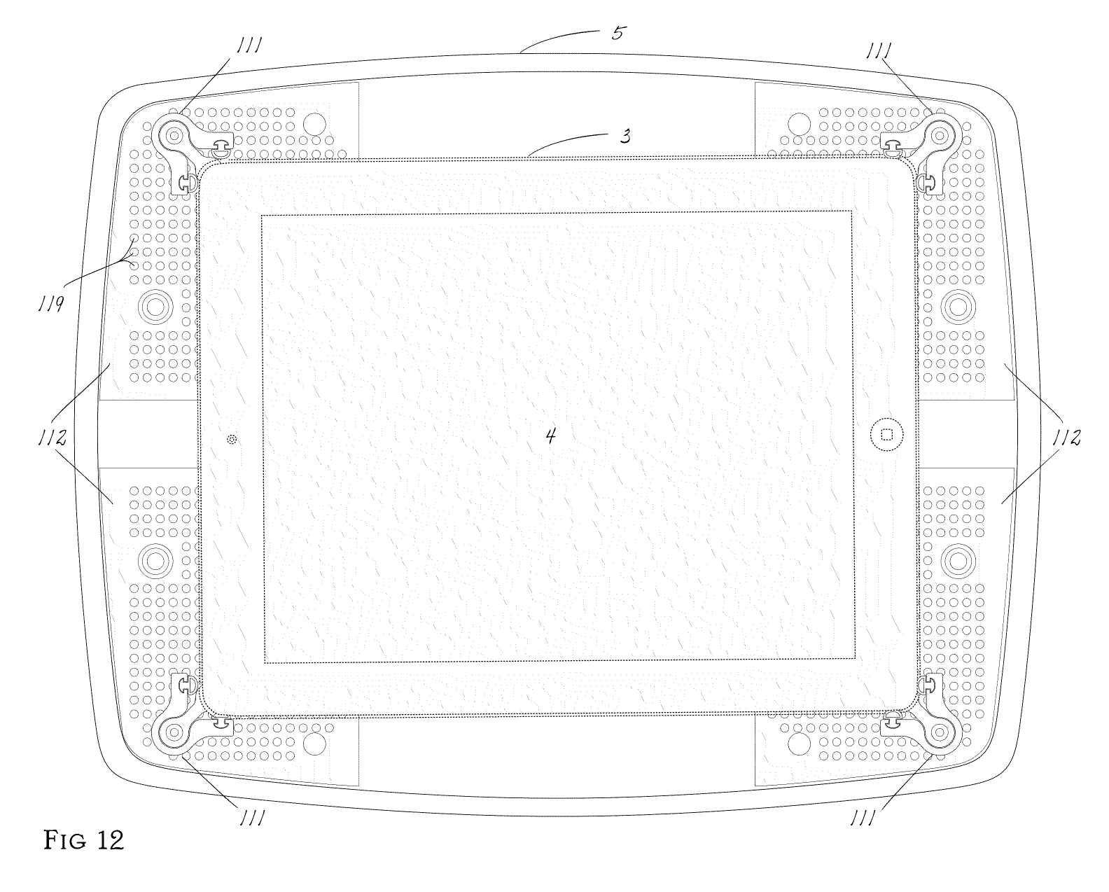

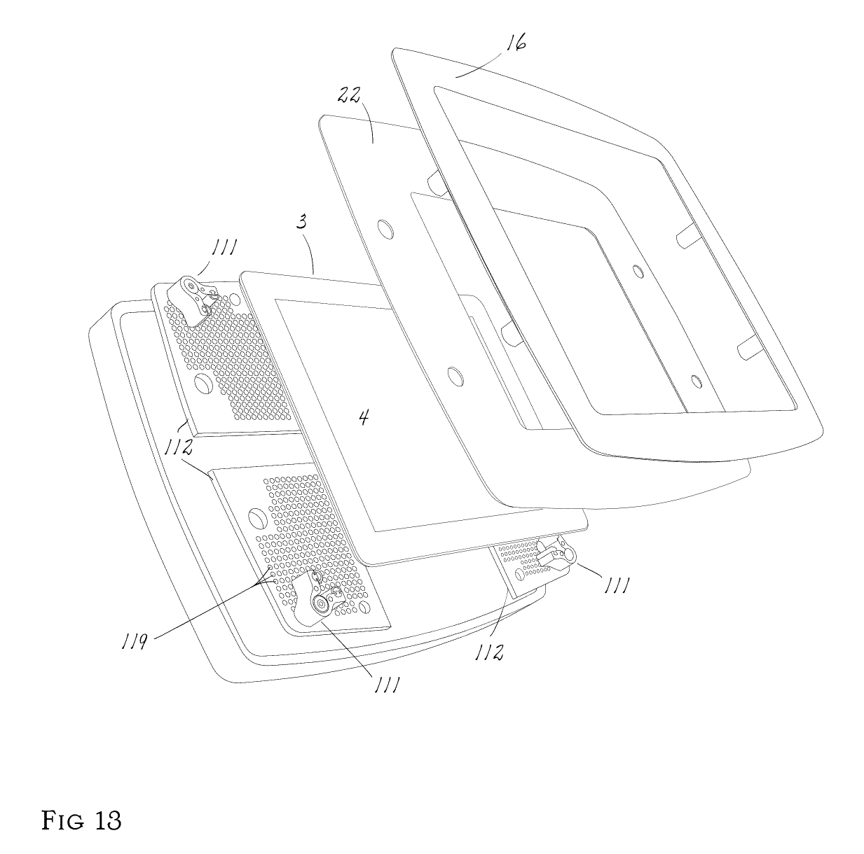

Referring now to FIGS. 11 to 16, an alternative embodiment uses standardized inserts 111, instead of having different-sized inserts for different devices. The standardized inserts are installable in any one of a number of positions provided by one or more mounting plates 112 installed in the housing 5. Preferably, there are four mounting plates, as illustrated in FIGS. 11 to 14, i.e. one for each corner of the unit, but several plates could be joined, or there could be just one plate covering the necessary area, with associated cost and weight penalties, however.

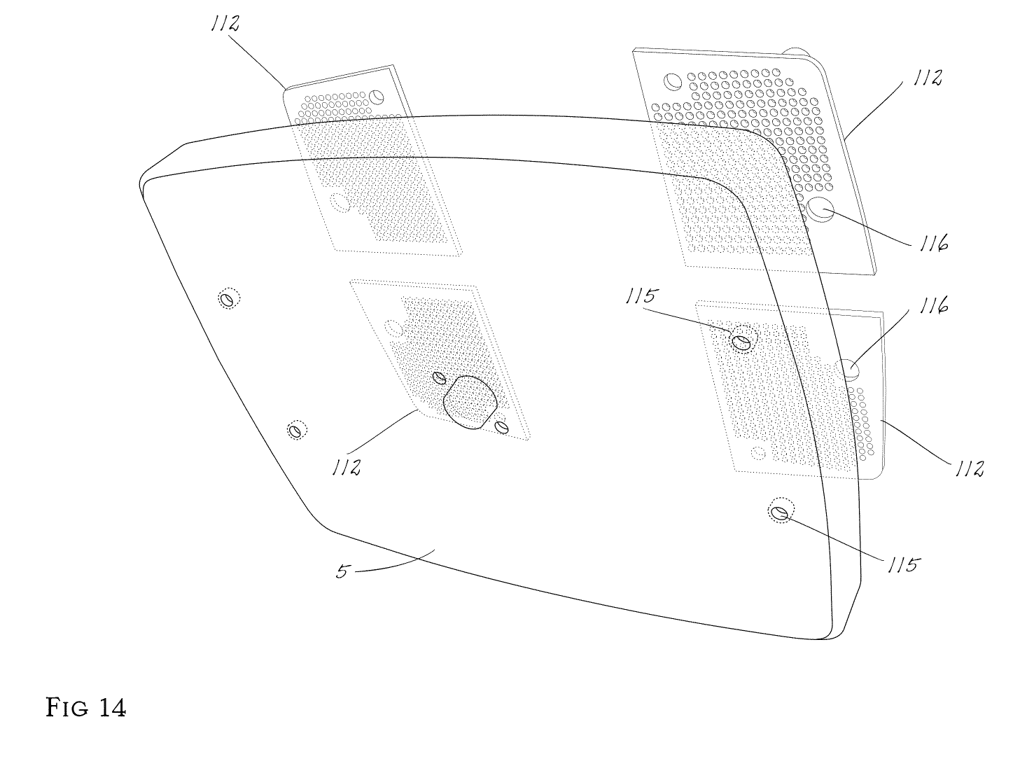

The mounting plates are positioned in the housing by any suitable means. The specific positioning means is not critical to the invention. For example, the mounting plates could be screwed to the housing, or positioned by pins 115 engaging holes 116 as shown in FIG. 14, similar to how the inserts are mounted in the housing in the earlier-described embodiments. The housing walls prevent the mounting plates from rotating on the pins (or additional pins could be used). Alternatively, the inserts could be somewhat free-floating at the time of assembly, only being locked in position when the face plate 16 is secured in place. Of course, once the assembly is complete, the mounting plates must be securely positioned, and the inserts must be securely positioned on the mounting plates, so that the device is held in position without potential rattling.

As an alternative to securing the mounting plates to the housing, the plates could be integrally formed with the housing, i.e. a planar surface could be provided as part of the housing, to constitute the mounting plates.

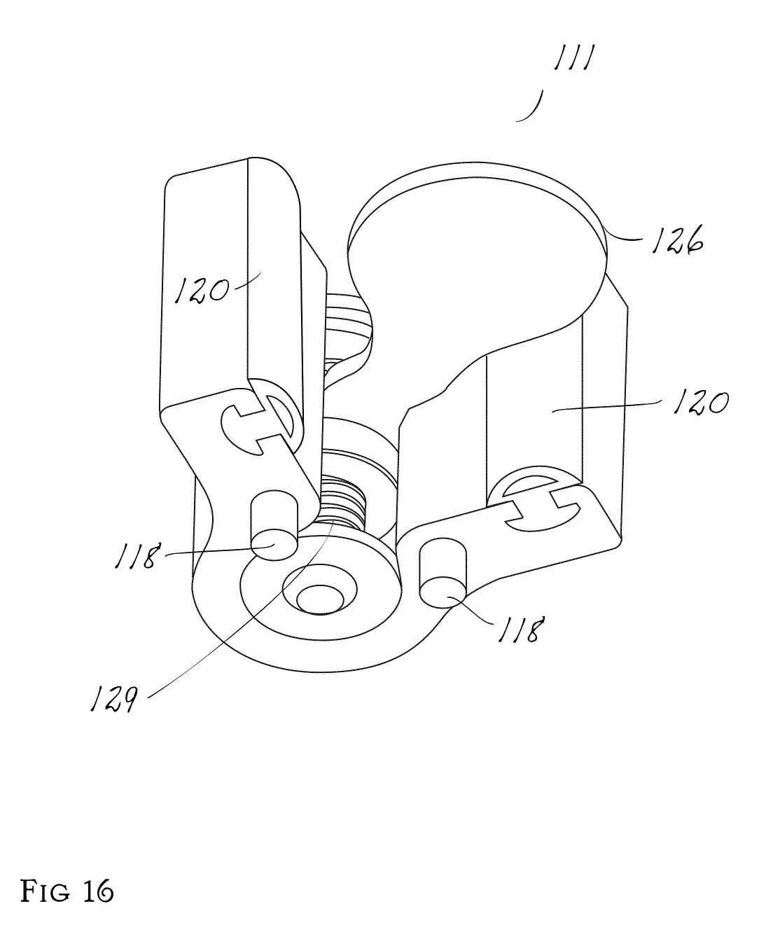

As seen best in FIG. 16, the inserts 111 may have pins 118 projecting from them, to engage holes 119 in the mounting plates. The mounting plates have enough holes and close enough hole spacing to accommodate a wide variety of device sizes. Although generally cylindrical pins are illustrated, it should be understood that other shapes could be used, i.e. the word “pin” should be interpreted broadly. As illustrated, two pins are provided so that the insert cannot rotate relative to the mounting plate. However, a single pin potentially could be used if an irregular (non-cylindrical) shape was used, or the inserts could be free to rotate until the device is installed, since the device would then hold them in position. Obviously this might slightly complicate the installation of the device, since each insert would have to be moved to the correct orientation as the device was being installed.

The inserts preferably include elastomeric bumpers 120 positioned to contact an installed device in a cushioned fashion, for a secure and quiet connection, i.e. no rattling.

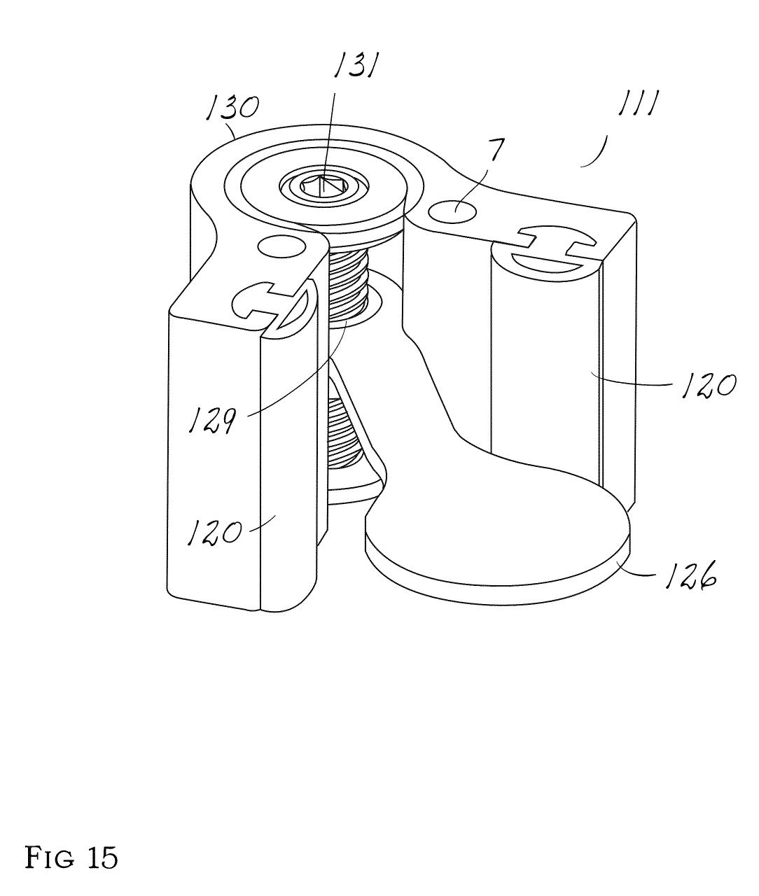

Each insert could have a fixed height platform on which the device could rest, potentially with spacers on the platform for thinner devices. However, as seen best in FIGS. 15 and 16, the inserts preferably but not necessarily have an adjustable-height platform 126. A lead screw 129 is captured in conventional fashion in a cylindrical portion 130 of the insert and the platform 126 has a threaded opening around the lead screw, so that the platform rides up and down with rotation of the lead screw. The lead screw may have, for example, a hex head 131 so that the platform can be easily set to the correct height for the intended device. The platform extends out from the cylindrical portion to support the device.

It should be realized that a height-adjustable platform could be adapted to the other embodiments described above. However, in the embodiments with non-standardized inserts, i.e. those with customized inserts to suit the selected device, the inserts can be configured to the correct height for the particular device, with generally no need for adjustment.

It should be clear that the invention need not be constructed exactly as described and illustrated here. A number of possible variations will be apparent to those who are knowledgeable in the field of the invention, and such variations are considered to be within the scope of the invention as defined by the claims which follow, i.e. the invention is not limited to the specific embodiments described and illustrated here.

For example, in relation to the embodiment of FIGS. 11 to 16, it should be apparent that neither the inserts 111 nor the mounting plates 112 need to be configured as shown. There could be wide variations in their shapes, configurations and methods of installation and connection to each other, within the scope of the invention.

1. A device holder assembly for an electronic display device, configured to receive and secure the device, the device holder assembly comprising:
a housing defining an insert cavity sized larger than the device;
at least one insert positionable within the insert cavity, the insert(s) having inner surfaces defining a device cavity configured to receive the device; and
a face plate securable to the housing over the insert(s) and device, the face plate having an opening sufficiently large to expose a desired display area of the device;
whereby devices of different sizes may be used in the device holder assembly by selection of insert(s) defining a device cavity appropriately sized and shaped for the selected device.

2. A device holder assembly as in claim 1, wherein at least one mounting plate is provided in said housing, and wherein at least one said insert is positionable in any one of a number of positions on said mounting plate.

3. A device holder assembly as in claim 2, wherein each said insert has at least one pin extending therefrom, to engage at least one corresponding hole in said mounting plate, to position said insert on said mounting plate.

4. A device holder assembly as in claim 2, wherein there are four said mounting plates, corresponding to four corners of said housing.

5. A device holder assembly as in claim 1, wherein said inserts each further comprise a height-adjustable platform to support the device at whatever height is dictated by the device thickness.

6. A device holder assembly as in claim 2, wherein said inserts each further comprise a height-adjustable platform to support the device at whatever height is dictated by the device thickness.

7. A device holder assembly as in claim 6, wherein said height-adjustable platform comprises an arm with a threaded hole mounted on a rotatable lead screw, captured in said insert.

8. A device holder assembly as in claim 2, further comprising a frame positioned between the face plate and the housing to overlie the device, the frame also having an opening sufficiently large to expose a desired display area of the device.

9. A device holder assembly as in claim 8, wherein the opening of the face plate is sufficiently large to expose the desired display area of the largest device which could fit within the housing, whereby a kit specific to a smaller device can comprise a frame with an appropriately-sized smaller opening for the device.

10. A device holder assembly as in claim 2, wherein the support structure comprises a first element securable to said rear surface of said housing, and at least one additional element securable to said first element, the selection of said elements providing various configuration options for said display stand assembly.

11. A device holder assembly as in claim 10, wherein one said additional element is a base plate configured to support said device holder assembly above a generally horizontal surface.

12. A device holder assembly as in claim 11, further comprising at least one extension element between said first element and said base plate, to support said device holder assembly at a greater distance above a generally horizontal surface than without said extension element.

13. A device holder assembly as in claim 10, wherein said elements are hollow to permit routing of cables therethrough, to and/or from the device.

14. A device holder assembly as in claim 10, wherein said first element is secured to said housing by a ball joint assembly, whereby the position of said housing relative to said support assembly can be varied.

15. A device holder assembly as in claim 14, wherein said elements and said ball joint assembly are hollow to permit routing of cables therethrough, to and/or from the device.
